(19) United States
(12) Patent Application Publication
(10) Pub. No.: US 2006/0141777 A1
(43) Pub. Date: Jun. 29, 2006

(54) Methods for patterning a layer of a semiconductor device

(76) Inventor: Yeong-Sil Kim, Suwon-city (KR)

Correspondence Address: HANLEY, FLIGHT & ZIMMERMAN, LLC, 20 N. WACKER DRIVE, SUITE 4220, CHICAGO, IL, 60606, US

(21) Appl. No.: 11/315,617

(22) Filed: Dec. 22, 2005

(30) Foreign Application Priority Data
Dec. 23, 2004 (KR) 10-2004-0111044

(51) Int. Cl. H01L 21/4763

(52) U.S. Cl. 438/638; 438/637

(57) ABSTRACT

A patterning layer of a single or multiple layer structure formed on a lower layer may be etched to form one or more steps therein, when the patterning layer is first dry etched to a partial depth thereof using a first resist pattern and then the patterning layer is etched again using a second resist pattern formed by lateral etching of the first resist pattern.

### FIELD OF THE DISCLOSURE

The present disclosure relates generally to semiconductor fabrication, and, more particularly, to methods for patterning an etching layer using a resist.

### BACKGROUND

As semiconductor devices have become increasingly highly integrated and products using the same have become increasingly diversified, various patterning methods are required in processes of manufacturing semiconductor devices.

FIG. 1A and FIG. 1B are cross-sectional views showing sequential stages of a conventional method for patterning an etching layer of a semiconductor device.

As shown in FIG. 1A, an etching layer 110 is deposited on a lower layer 100.

Subsequently, a photoresist 120 is deposited on the etching layer 110. In addition, the photoresist 120 is patterned by a photolithography method according to a required pattern of the etching layer 110.

As shown in FIG. 1B, the etching layer 110 is patterned by dry etching using such patterned photoresist 120 as a mask.

In the case that a phbtoresist is used as an etch stop layer, a pattern as shown in FIG. 1B is generally obtained. Such a conventional patterning method is focused on satisfying a critical dimension (CD).

However, as products employing semiconductor devices have become more diversified, manufacturing processes should accordingly be diversified, and thus various patterning methods are required.

### BRIEF DESCRIPTION OF THE DRAWINGS

FIG. 1A and FIG. 1B are cross-sectional views showing sequential stages of a conventional method for patterning an etching layer of a semiconductor device.

FIG. 2A to FIG. 2E are cross-sectional views showing sequential stages of an example method for patterning an etching layer of a semiconductor device performed in accordance with the teachings of the present invention.

FIG. 3A to FIG. 3G are cross-sectional views showing sequential stages of another example method for patterning an etching layer of a semiconductor device performed in accordance with the teachings of the present invention.

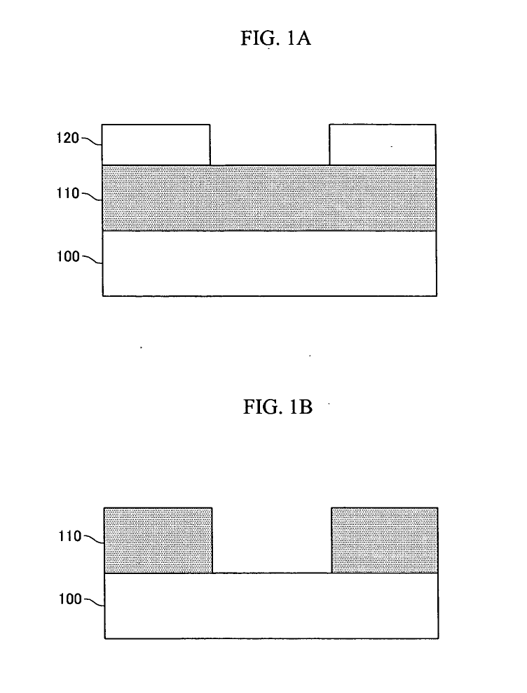

To clarify multiple layers and regions, the thickness of the layers are enlarged in the drawings. Wherever possible, the same reference numbers will be used throughout the drawing(s) and accompanying written description to refer to the same or like parts. As used in this patent, stating that any part (e.g., a layer, film, area, or plate) is in any way positioned on (e.g., positioned on, located on, disposed on, or formed on, etc.) another part, means that the referenced part is either in contact with the other part, or that the referenced part is above the other part with one or more intermediate part(s) located therebetween. Stating that any part is in contact with another part means that there is no intermediate part between the two parts.

### DETAILED DESCRIPTION

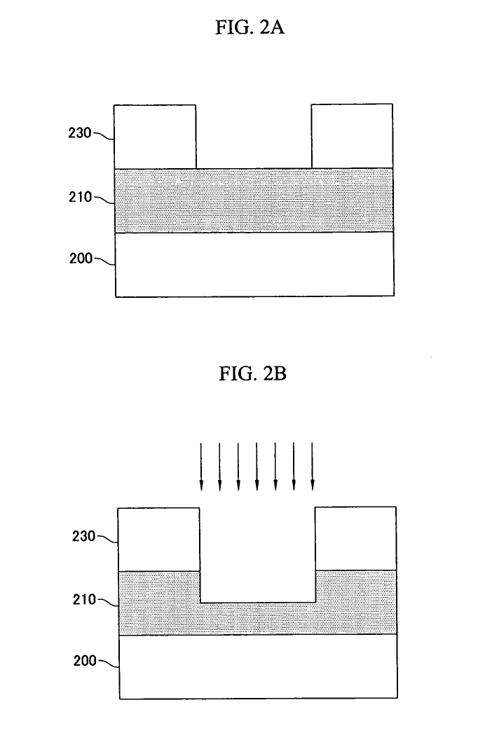

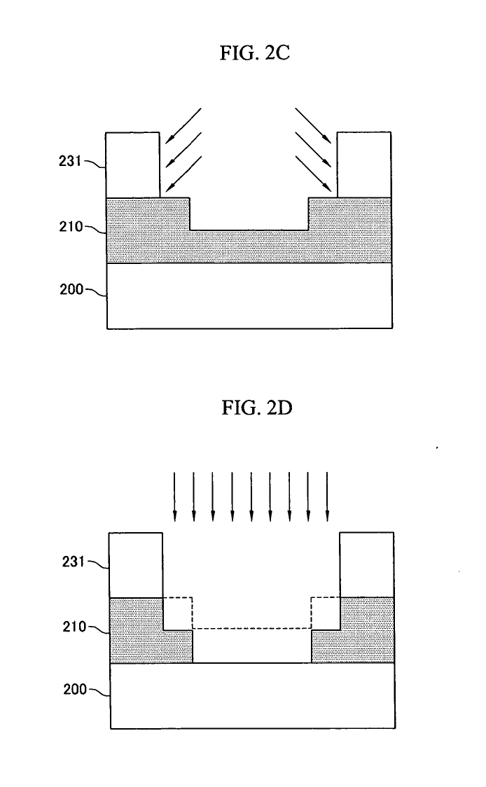

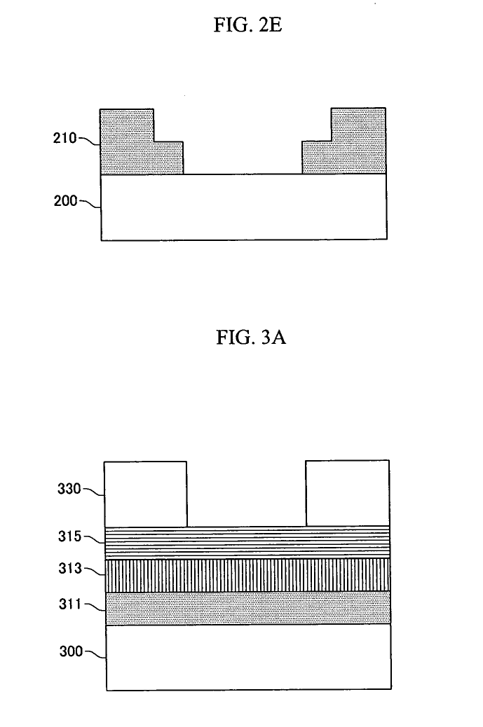

An example patterning method performed in accordance with the teachings of the present invention will hereinafter be described in detail with reference to FIG. 2A to FIG. 2E.

FIG. 2A to FIG. 2E are cross-sectional views showing sequential stages of an example method for patterning an etching layer of a semiconductor device performed in accordance with the teachings of the present invention.

As shown in FIG. 2A, an etching layer 210 is deposited on a lower layer 200 formed on a semiconductor substrate. In the illustrated example, the etching layer 210 may be formed as a silicon oxide layer or a polysilicon layer. In addition, the lower layer 200 may be partially etched using a pattern that will be formed in the etching layer 210.

By depositing a resist (e.g., a photoresistive material) on the etching layer 210 and patterning the resist using a lithographic process, a first resist pattern 230 is formed as shown in FIG. 2A.

Then, referring to FIG. 2B, a first etching process is performed using the first resist pattern 230 as a mask to etch the etching layer 210 to a partial depth thereof (i.e., to an amount less than the entire thickness of the etching layer 210).

When the etching layer 210 is formed as a silicon oxide layer, a CF-based gas may be used as a main etchant gas in the first etching process. In addition, additional gases such as oxygen (O₂), argon (Ar), and nitrogen (N₂) may be added thereto so as to improve etching uniformity.

If the etching layer 210 is formed as a polysilicon layer, either one of or a combination of a bromide gas, a chloride gas, and an inorganic fluoride gas may be used as a main etchant gas. The bromide gas may be selected from a group consisting of HBr, Br₂, and CH₃Br. The chloride gas may be selected from a group consisting of C1₂, and HCl. The inorganic fluoride gas may be selected from a group consisting of NF₃, CF₄, and SF₆.

A power source for maintaining generation of plasma and a bias power for causing ion bombardment are applied to a chamber filled with such an etchant gas.

As shown in FIG. 2B, the etching layer 210 is only partially etched (e.g., to a partial depth) through the first dry etching process such that the lower layer 200 is not exposed by the first dry etching process.

Subsequently, as shown in FIG. 2C, a second resist pattern 231 is formed by lateral etching of the first resist pattern 230. In the illustrated example, O₂ gas is used as a main etchant gas for lateral etching of the first resist pattern 230. Furthermore, additional gases such as argon (Ar), helium (He), and nitrogen (N₂), which are not the main etchant gas for the etching layer 210, may be added to improve etching uniformity of the lateral etching of the first resist pattern 230. A power source and/or a bias power are applied to the main etchant gas and the additional gas. Accordingly, oxygen radicals are formed by applying the power, and isotropic etching of the resist is performed by the oxygen radicals. Therefore, the second resist pattern 231 may be formed as shown in FIG. 2C.

Now, referring to FIG. 2D, the etching layer 210 is dry etched again; this time while using the second resist pattern 231 as an etching mask. In the illustrated example, if the etching layer 210 is formed as a silicon oxide layer, a CF-based gas may be used as a main etchant gas in the second etching process. Additional gases such as oxygen (O₂), argon (Ar), and nitrogen (N₂) may be added to the main etchant gas so as to improve etching uniformity. In addition, a power source for maintaining generation of plasma and a bias power for causing ion bombardment are applied to a chamber filled with the etchant gas.

If the etching layer 210 is formed as a polysilicon layer, either one of, or a combination of, a bromide gas, a chloride gas, and an inorganic fluoride gas may be used as a main etchant gas. The bromide gas may be selected from a group consisting of HBr, Br₂, and CH₃Br. The chloride gas may be selected from a group consisting of Cl₂, and HCl. The inorganic fluoride gas may be selected from a group consisting of NF₃, CF₄, and SF₆. In addition, if higher selectivity is required according to the type of the lower layer 200, an additional gas such as O₂, and CHF₃ may be added.

Then, as shown in FIG. 2D, since the once-etched etching layer 210 is etched again using the second resist pattern 231 as a mask, the profile of the etching layer 210 is formed in a step shape, and the lower layer 200 is exposed.

Subsequently, as shown in FIG. 2E, the patterning of the etching layer 210 is finished by removing the second resist pattern 231.

As described above, an etching layer is first dry etched, and then the etching layer is dry etched again after lateral etching of the resist pattern/mask. Therefore, the etching layer may be formed to have one or more steps in its sectional view.

While the above example has been described with reference to a case wherein an etching layer is formed as a single layer, it is to be understood that these teachings ate not limited thereto, but instead may be applied to other situations, for example, to the case wherein the etching layer includes a plurality of layers. More specifically, the etching layer may be etched to produce a plurality of steps in its cross-sectional view, by a repetition of partial dry etching the etching layer and lateral etching of a resist layer/mask.

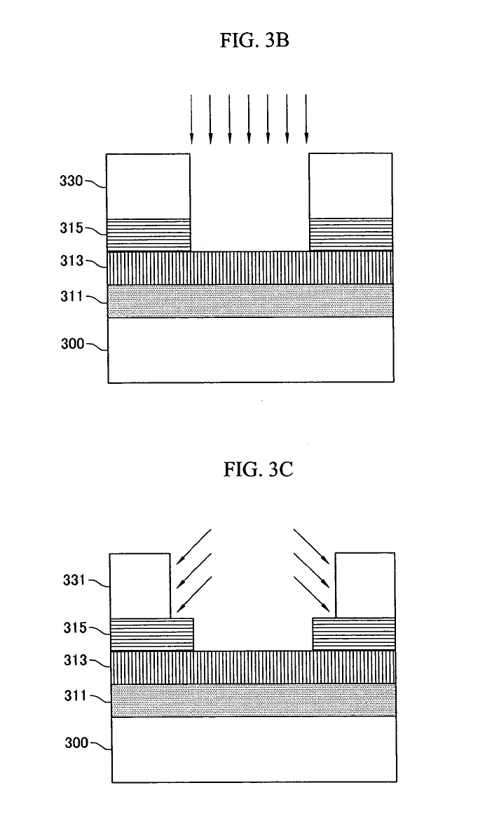

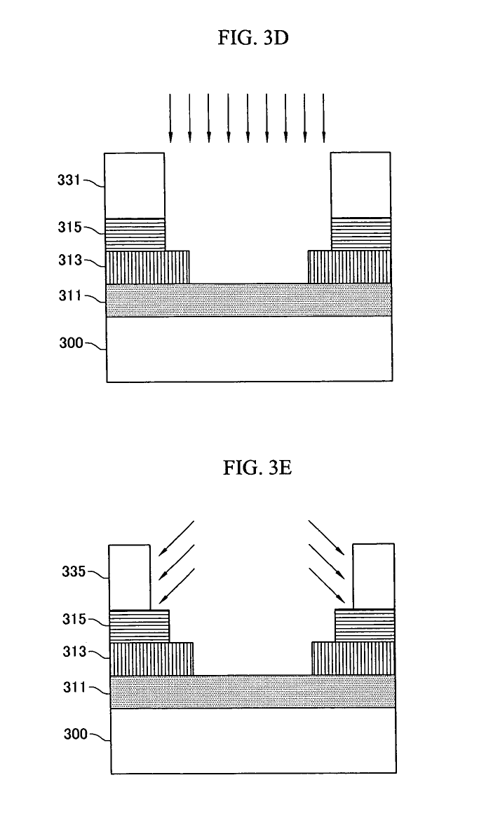

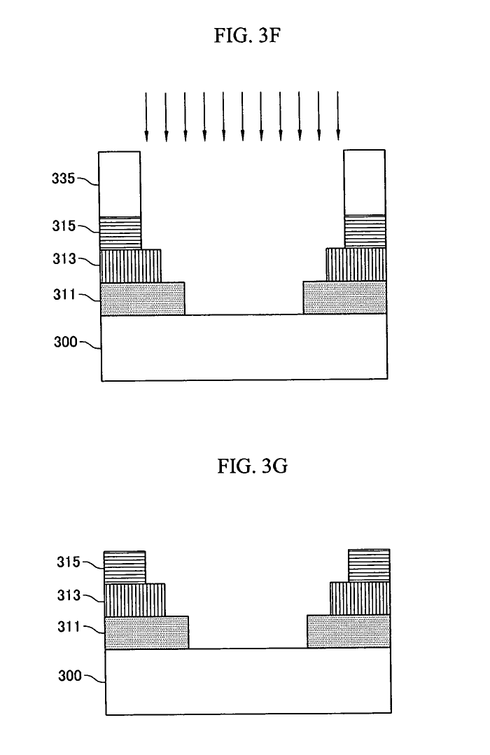

Another example patterning method performed in accordance with the teachings of the present invention will hereinafter be described in detail with reference to FIG. 3A to FIG. 3G.

FIG. 3A to FIG. 3G are cross-sectional views showing sequential stages of an example method for patterning an etching layer of a semiconductor device performed in accordance with the teachings of the present invention. In this example, the total etching layer that is to be patterned is not a single layer, but instead it includes a plurality of different individual layers.

As shown in FIG. 3A, first, second, and third etching layers 311, 313, and 315 are sequentially formed on a lower layer 300, and then a first resist pattern 330 is formed on the third etching layer using a lithographic process.

Then, as shown in FIG. 3B, the third etching layer 315 is dry etched using the first resist pattern 330 as a mask. Subsequently, as shown in FIG. 3C, a second resist pattern 331 is formed by lateral etching of the first resist pattern 330. Then, as shown in FIG. 3D, the third and second etching layers 315 and 313 are dry etched using the second resist pattern 331 as a mask.

Subsequently, as shown in FIG. 3E, a third resist pattern 335 is formed by lateral etching of the second resist pattern 331. Then, as shown in FIG. 3F, the third, second, and first etching layers 315, 313, and 311 are dry etched using the third resist pattern 335 as a mask.

Therefore, as shown in FIG. 3G, a pattern having three steps may be formed across the total etching layer including the three individual layers.

From the foregoing, persons of ordinary skill in the art will appreciate that, in an example process disclosed herein, a lower layer, a patterning layer to be patterned, and a resist layer are sequentially formed on a semiconductor substrate. In addition, the patterning layer is first dry etched using a patterned resist, and then, the patterning layer is dry etched again after lateral etching of the patterned resist. In such a process, a patterning layer may be patterned to have several steps in its cross-sectional view.

In addition, the types of etchant gases or a composition ratio thereof are not necessarily required to be changed when forming the multiple steps in the patterning layer, and therefore, a pattern having multiple steps may be easily formed.

Furthermore, an etching layer including a plurality of individual layers of different components may be etched to a pattern having multiple steps, by a simple repetition of dry etching the individual layer and lateral etching of the resist.

From the foregoing, persons of ordinary skill in the art will recognize that methods for forming a pattern have been provided which provide a step-shaped cross-section in a semiconductor device by dry etching a lateral side of a resist/mask pattern.

A disclosed example method for patterning a layer of a semiconductor device includes: forming a lower layer on a substrate; forming a patterning layer on the lower layer; forming a resist on the patterning layer; forming a first resist pattern by performing a lithographic process on the resist; partially dry etching the patterning layer using the first resist pattern as a mask such that the lower layer may not be exposed; forming a second resist pattern by dry etching a lateral side of the first resist pattern; and dry etching the patterning layer using the second resist pattern such that the lower layer may be exposed.

The patterning layer may be a layer used for at least partially etching the lower layer. In addition, the patterning layer may include silicon oxide or polysilicon.

Oxygen is used as a main etchant gas for dry etching the lateral sides of the first resist pattern. In addition, an additional gas different from the main etchant gas for the patterning layer is added to improve the uniformity of the lateral etching of the first resist pattern. In an example discussed above, the additional gas is one selected from a group consisting of argon, helium, and nitrogen.

Another disclosed example method for patterning a layer of a semiconductor device includes: forming a lower layer on a substrate; sequentially forming first and second patterning layers on the lower layer; forming a resist on the patterning layers; forming a first resist pattern by performing a lithographic process on the resist; dry etching the second patterning layer using the first resist pattern; forming a second resist pattern by dry etching a lateral side of the first resist pattern; and dry etching the first and second patterning layers using the second resist pattern.

In such an example, oxygen may be used as a main etchant gas for dry etching the lateral side of the first resist pattern. In addition, an additional gas different from main etchant gases for the first and second patterning layers may be added to improve uniformity of the lateral etching of the first resist pattern.

The additional gas may be one selected from a group consisting of argon, helium, and nitrogen.

A third patterning layer may be formed on the lower layer prior to the first and second patterning layers.

In addition, the example method may further include: forming a third resist pattern by dry etching a lateral side of the second resist pattern; and dry etching the first, second, and third patterning layers using the third resist pattern.

It is noted that this patent claims priority from Korean Patent Application Serial Number 10-2004-0111044, which was filed on Dec. 23, 2004, and is hereby incorporated by reference in its entirety.

Although certain example methods, apparatus and articles of manufacture have been described herein, the scope of coverage of this patent is not limited thereto. On the contrary, this patent covers all methods, apparatus and articles of manufacture fairly falling within the scope of the appended claims either literally or under the doctrine of equivalents.

What is claimed is:

1. A method for patterning a layer of a semiconductor device, comprising:
forming a lower layer on a substrate;
forming a patterning layer on the lower layer;
forming a resist on the patterning layer;
forming a first resist pattern by performing a lithographic process on the resist;
partially dry etching the patterning layer using the first resist pattern as a mask such that the lower layer is not exposed;
forming a second resist pattern by dry etching a lateral side of the first resist pattern; and
dry etching the patterning layer using the second resist pattern such that the lower layer is exposed.

2. A method as defined in claim 1, wherein the patterning layer is a mask layer used for at least partially etching the lower layer.

3. A method as defined in claim 1, wherein the patterning layer comprises silicon oxide or polysilicon.

4. A method as defined in claim 1, wherein oxygen is a main etchant gas for dry etching the lateral side of the first resist pattern.

5. A method as defined in claim 4, wherein an additional gas different from the main etchant gas is used to improve uniformity of the lateral etching of the first resist pattern.

6. A method as defined in claim 5, wherein the additional gas is one selected from a group consisting of argon, helium, and nitrogen.

7. A method for patterning a layer of a semiconductor device, comprising:
forming a lower layer on a substrate;
sequentially forming first and second patterning layers on the lower layer;
forming a resist on the patterning layers;
forming a first resist pattern by performing a lithographic process on the resist;
dry etching the second patterning layer using the first resist pattern as a mask;
forming a second resist pattern by dry etching a lateral side of the first resist pattern; and
dry etching the first and second patterning layers using the second resist pattern as a mask.

8. A method as defined in claim 7, wherein oxygen is used as a main etchant gas for dry etching the lateral side of the first resist pattern.

9. A method as defined in claim 8, wherein an additional gas different from the main etchant gas is used to improve uniformity of the lateral etching of the first resist pattern.

10. A method as defined in claim 9, wherein the additional gas is one selected from a group consisting of argon, helium, and nitrogen.

11. A method as defined in claim 7, wherein a third patterning layer is formed on the lower layer prior to the first and second patterning layers.

12. A method as defined in claim 11, further comprising:
forming a third resist pattern by dry etching a lateral side of the second resist pattern; and
dry etching the first, second, and third patterning layers using the third resist pattern as a mask.
